(19) United States
(12) Patent Application Publication
(10) Pub. No.: US 2012/0299173 A1
(43) Pub. Date: Nov. 29, 2012

(54) Thermally Enhanced Stacked Package and Method

(75) Inventors: Anwar A. Mohammed, San Jose, CA (US); Weifeng Liu, Shenzhen (CN)

(73) Assignee: FutureWei Technologies, Inc., Plano, TX (US)

(21) Appl. No.: 13/446,874

(22) Filed: Apr. 13, 2012

Related U.S. Application Data
(60) Provisional application No. 61/490,513, filed on May 26, 2011.

(51) Int. Cl. H01L 23/34; H01L 21/50

(52) U.S. Cl. 257/686; 438/107; 257/E23.08; 257/E21.499

(57) ABSTRACT

A package-on-package (PoP) device is provided. The device includes a first package with a first chip mounted on a first substrate, a heat spreader stacked on the first package, the heat spreader in thermal contact with the first chip, and a second package stacked on the heat spreader. In an embodiment, the heat spreader is formed using carbon fibers to provide good lateral thermal conductivity. In an embodiment, ends of the heat spreader project beyond a periphery of the first and second packages.

This patent application claims priority to U.S. Provisional Application No. 61/490,513, filed on May 26, 2011, entitled “Thermally Enhanced Stacked Package,” which is incorporated by reference herein as if reproduced in its entirety.

### TECHNICAL FIELD

The present disclosure relates to electronic components and methods, and, in particular embodiments, to a thermally enhanced stacked package, e.g., using high conductivity (x and y plane) lateral heat spreaders as fins.

### BACKGROUND

Package on Package (PoP) is an integrated circuit packaging technique to allow vertically combining discrete logic and memory ball grid array (BGA) packages. Two or more packages are installed on top of one another, i.e. stacked, with a standard interface to route signals between them. This allows higher density, for example in the mobile telephone/PDA market.

A system-in-a-package or system in package (SiP), also known as a chip stack multi-chip module, includes a number of integrated circuits enclosed in a single package or module. In some examples, the electronics in the SiP performs all or most of the functions of an electronic system, and are typically used inside a mobile phone, digital music player, etc. Integrated circuit dies containing integrated circuits may be stacked vertically on a substrate and to the package with bond wires. They are internally connected by fine wires that are bonded to the package. Alternatively, with a flip chip technology, solder bumps are used to join stacked chips together. SiP dies are stacked vertically, unlike slightly less dense multi-chip modules, which place dies horizontally alongside one another. SiP connects the dies with standard off-chip wire bonds or with solder bumps, unlike slightly denser three-dimensional (3D) integrated circuits that connect stacked silicon dies with conductors running through the die.

An example SiP may contain several chips (e.g., such as a specialized processor, DRAM, flash memory) combined with passive components (e.g., resistors and capacitors) all mounted on the same substrate. This means that a complete functional unit can be built in a multi-chip package, so that few external components need to be added to make it work. This is particularly valuable in space constrained environments like MP3 players and mobile phones as it reduces the complexity of the printed circuit board and overall design. Despite its benefits, this technique may encounter yield issues because a defective chip in the package may result in a non-functional packaged integrated circuit, even if all other modules in that same package are functional.

Because of the relentless industry demand for added speed, power, and functionality in reduced package footprints, microelectronics packages are leaning towards 3D packaging. In that regard, thermal management has become a particular challenge. Heat dissipation from individual components may cause an increased rise in the integrated module temperature, especially when a high power component (e.g., logic) is integrated into the module. Further, some components (e.g., memory) are relatively sensitive to the thermal environment.

Aspects of this disclosure offer a 3D package approach with significantly better thermal management at a substantially lower price.

### SUMMARY

In an embodiment, a package-on-package (PoP) device includes a first package, a heat spreader, and a second package. The first package has a first chip mounted on a first substrate. The heat spreader is stacked on the first package and is in thermal contact with the first chip. The second package stacked on the heat spreader.

In an embodiment, a package-on-package (PoP) device includes a first package, a heat spreader, and a second package. The first package has a first chip mounted on a first substrate. The first heat spreader is stacked on the first package and is in thermal contact with the first chip. The second package is stacked on the first heat spreader and includes a second chip mounted on a second substrate.

In an embodiment, a method of constructing a package-on-package (PoP) device includes stacking a heat spreader on a first package, the heat spreader in thermal contact with a first chip mounted on the first package, and stacking a second package on the heat spreader.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 is a top plan view of an embodiment Package-on-Package (PoP) device including a heat spreader;

FIG. 2 is a cross section of the PoP device of FIG. 1 taken generally along line 2-2;

FIG. 3 is a cross section of the PoP device of FIG. 1 taken generally along line 3-3;

FIG. 4 is an embodiment PoP device including a heat insulating film;

FIG. 5 is an embodiment PoP device having chips disposed on opposing sides of the heat spreader;

FIGS. 6a-6i collectively illustrate an embodiment of a process of forming an embodiment PoP device incorporating heat spreaders; and

FIG. 7 illustrates a method of forming the PoP device of FIG. 1.

### DETAILED DESCRIPTION OF ILLUSTRATIVE EMBODIMENTS

The making and using of the present embodiments are discussed in detail below. It should be appreciated, however, that the present disclosure provides many applicable inventive concepts that can be embodied in a wide variety of specific contexts. The specific embodiments discussed are merely illustrative and do not limit the scope of the disclosure.

The present disclosure will be described with respect to stacked packages, namely, Package-on-Package (PoP), Package-in-Package (PiP), and System-in-Package (SiP) devices. The concepts of the present disclosure may also be applied, however, to other semiconductor devices or processes in general.

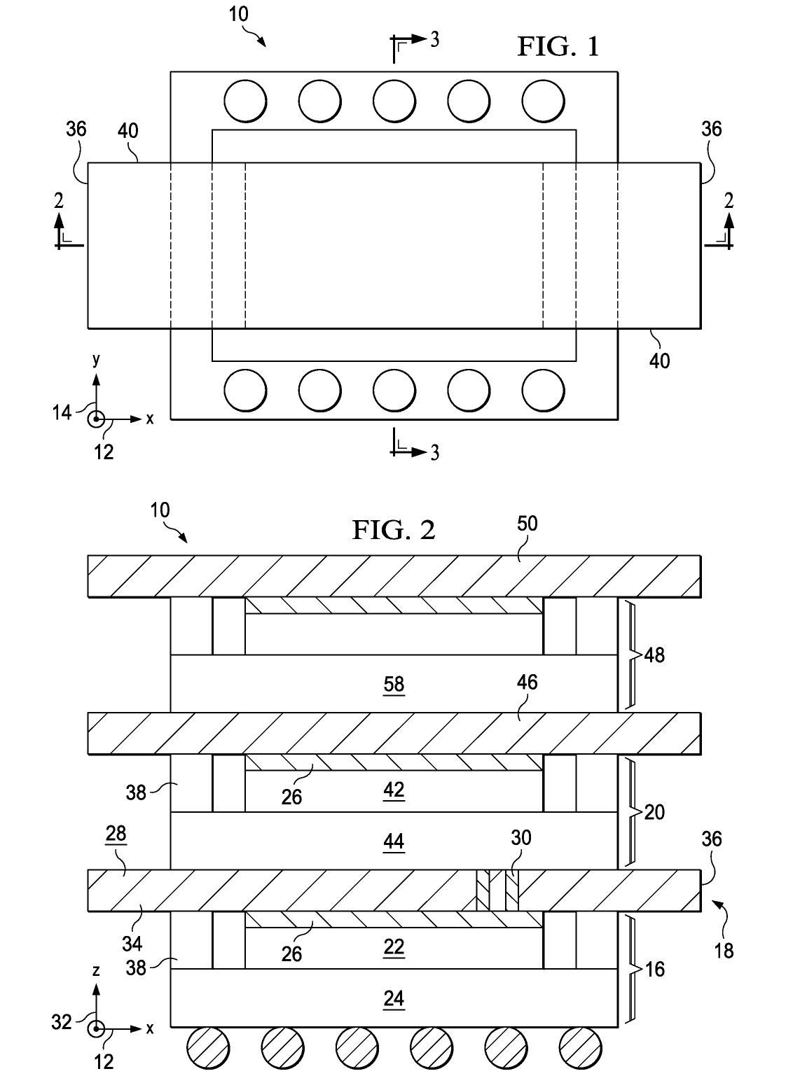

Referring collectively to FIGS. 1-3, an embodiment of a PoP device 10 is illustrated. As will be more fully explained below, the PoP device 10 provides a thermally efficient three-dimensional (3D) package with a limited footprint and high lateral thermal conductivity. As used herein, lateral refers to the x-direction 12 (or plane) and the y direction 14 (or plane). As illustrated in FIGS. 1-3, the PoP device 10 generally includes a first package 16, a first heat spreader 18, and a second package 20.

The first package 16 includes a first chip 22 (a.k.a., die) mounted on a first printed circuit board (PCB) substrate 24. The first chip 22 may be, for example, a logic chip or a memory chip. The first PCB substrate 24 may include various traces, contact pads, vias, and other circuitry or features which, for ease of illustration, have not been shown in FIGS. 1-3. In addition, while the first PCB substrate 24 is illustrated in FIGS. 1-3 as a single layer, the first PCB substrate 24 may be formed from several layers. The first PCB substrate 24 may be formed using typical or conventional printed circuit board fabrication processes or techniques.

The first heat spreader 18 is generally stacked on the first PCB substrate 24 of the first package 16. In such a configuration, the first heat spreader 18 is in thermal contact with the first chip 22. In an embodiment, a thermally conductive pad 26 (a.k.a., a thermal interface material) is disposed between the first heat spreader 18 and the first chip 22 of the first package 16. In an embodiment, the thermally conductive pad 26 is formed from, for example, a phase change material, a thermally conductive gel, grease, and so on. In an embodiment, the first heat spreader 18 includes a central portion that drops or extends downwardly into the cavity in order to directly contact the first chip 22. In such cases, the thermally conductive pad 26 may also be used or, in the alternative, omitted.

In an embodiment, the first heat spreader 18 is formed using carbon fibers 28. The carbon fibers 28 may be held together using an adhesive or other suitable material. In an embodiment, the first heat spreader 18 may be formed using other thermally conductive metals or materials such as, for example, copper, aluminum, or diamond.

In an embodiment, the first heat spreader 18 is provided with copper filled vias 30 (FIG. 2) in order to, for example, improve vertical thermal conductivity. As used herein, vertical refers to the z-direction 32 (or plane). In an embodiment, the first heat spreader 18 is plated with metal 34 (e.g., copper) in order to, for example, inhibit carbon fiber droppings.

In those embodiments where the first heat spreader 18 is formed using carbon fibers 28 and is copper plated, the first heat spreader 18 may have a density of about 1.85 grams per cubic centimeter (gm/cm³). In an embodiment, the density is about 2.7 gm/cm³ for anodized aluminum and about 8.92 gm/cm³ for plated copper, which may also be suitably used. Therefore, in some embodiments the PoP device 10 employing the first heat spreader 18 formed from carbon fibers 28 may be particularly suitable for use in weight sensitive applications (e.g., military and aerospace devices).

The first heat spreader 18 also has a thermal conductivity in the lateral direction (the x and y directions) of between about 600 Watts per meter per Kelvin (W/(m-K)) and about 1,500 W/(m-K). In an embodiment, the thermal conductivity is about 220 W/(m-K) for anodized aluminum and about 394 for plated copper, which may also be suitably used. Therefore, the first heat spreader 18 is able to laterally dissipate heat away from the first chip 22 very efficiently.

In addition, the first heat spreader 18 has a coefficient of thermal expansion of about 5 parts per million per degree Celsius (ppm/° C.). In an embodiment, the thermal expansion is about 27 ppm/° C. for anodized aluminum and about 17 ppm/° C. for plated copper, which may also be suitably used. Another benefit is that the cost of fabricating the first heat spreader 18 using the carbon fibers 28 is approximately the same as the cost of forming a heat spreader using, for example, anodized aluminum.

Those skilled in the art will appreciate that the properties and/or characteristics of the first heat spreader 18 may be further improved or modified based on, for example, the alignment of the carbon fibers 28 in the first heat spreader 18, the percentage of carbon fibers 28 in the first heat spreader 18, whether the carbon fibers 28 have been enhanced to increase the surface area, and so forth.

As shown in FIGS. 1-2, in an embodiment, ends 36 of the first heat spreader 18 extend beyond a periphery 38 of the first package 16, the second package 20, or both. In such a configuration, the first heat spreader 18 is able to function like, for example, the fin elements of a heat sink by providing more surface area for heat dissipation. In an embodiment, sides 40 of the first heat spreader 18 may also expand beyond the periphery 38 of the first package 16, the second package 20, or both.

As shown in FIGS. 1-3, in an embodiment the second package 20 is stacked directly upon the first heat spreader 18. The second package 20 includes a second chip 42 (a.k.a., die) mounted on a second printed circuit board (PCB) substrate 44. The second chip 42 may be, for example, a logic chip or a memory chip. The second PCB substrate 44 may include various traces, contact pads, vias, and other circuitry or features which, for ease of illustration, have not been depicted in FIGS. 1-3. In addition, while the second PCB substrate 44 is illustrated in FIGS. 1-3 as a single layer, the second PCB substrate 44 may be formed from several layers. The second PCB substrate 44 may be formed using typical or conventional printed circuit board fabrication processes or techniques.

Still referring to FIGS. 1-3, in an embodiment the PoP device 10 includes a second heat spreader 46, a third package 48, and a third heat spreader 50. As shown, the second heat spreader 46, the third package 48, and the third heat spreader 50 may be stacked upon each other in, for example, an alternating format. Other stacking formats may also be employed in other embodiments.

The second and third packages 20, 48 may be the same or substantially the same as the first package 16. In addition, the second and third heat spreaders 46, 50 may be the same or substantially the same as the first heat spreader 18. In the alternative, the second and third packages 20, 48 may be different than the first package 16 and the second and third heat spreaders 46, 50 may be different than the first heat spreader 18.

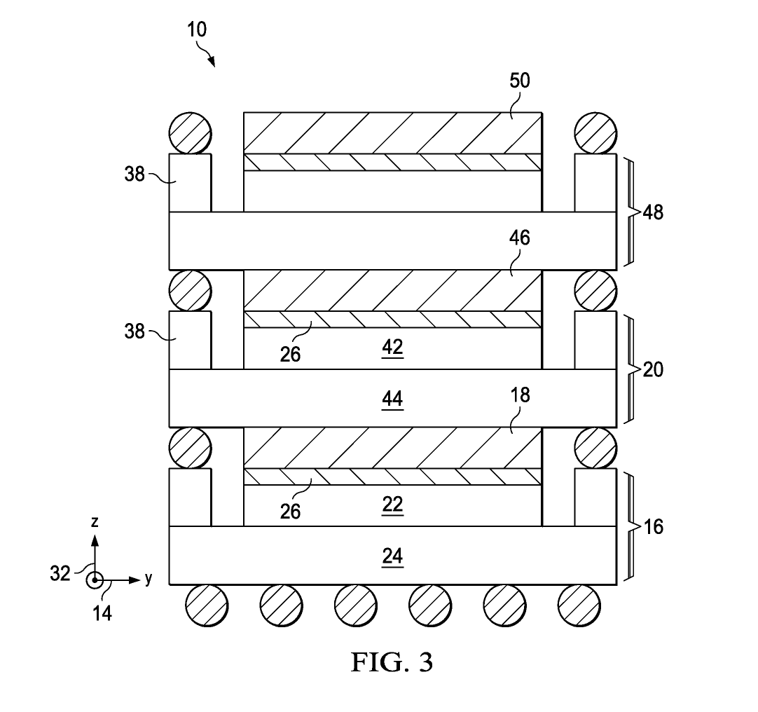

While the PoP device 10 of FIGS. 2-3 includes three total packages and three total heat spreaders, more packages and more heat spreaders may be incorporated into the PoP device 10 depending on, for example, the performance requirements of the PoP device 10, the amount of heat dissipation desired, and so on.

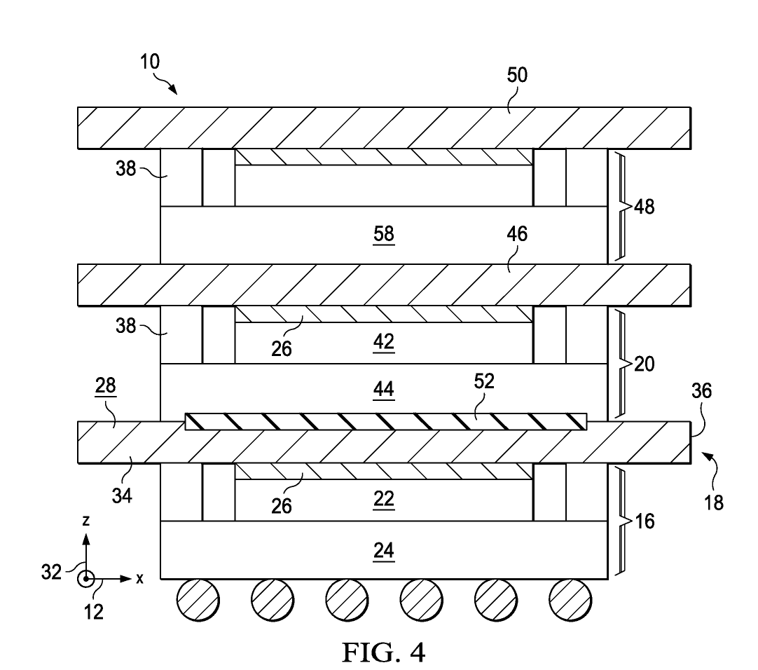

Referring now to FIG. 4, in an embodiment, first chip 22 in the PoP device 10 is a high power component. To accommodate the increased heat generated by the high power component, a heat insulating film 52 (i.e., an extra heat insulator) may be incorporated into the PoP device 10. In an embodiment, the heat insulating film 52 is disposed between the first heat spreader 18 and the second PCB substrate 44 directly above the high power component. The heat insulating film 52 may be embedded in the first heat spreader 18, in the second PCB substrate 44, or both. In an embodiment, the heat insulating film 52 is a biaxially-oriented polyethylene terephthalate (BoPET) film (which is commercially available under the trade name Mylar®). Alternatively, other materials may be suitably used. In an embodiment, the first heat spreader 18, the second PCB substrate 44, or both are free of any structures (e.g., copper filled vias 30 or thermal vias) directly above the high power component to inhibit or prevent conduction of heat in the z-direction 32. In an embodiment, the second PCB substrate 44 may also serve as an insulator in addition to, or instead of, the heat insulating film 52. In such embodiments, thermal vias are omitted from the second PCB substrate 44.

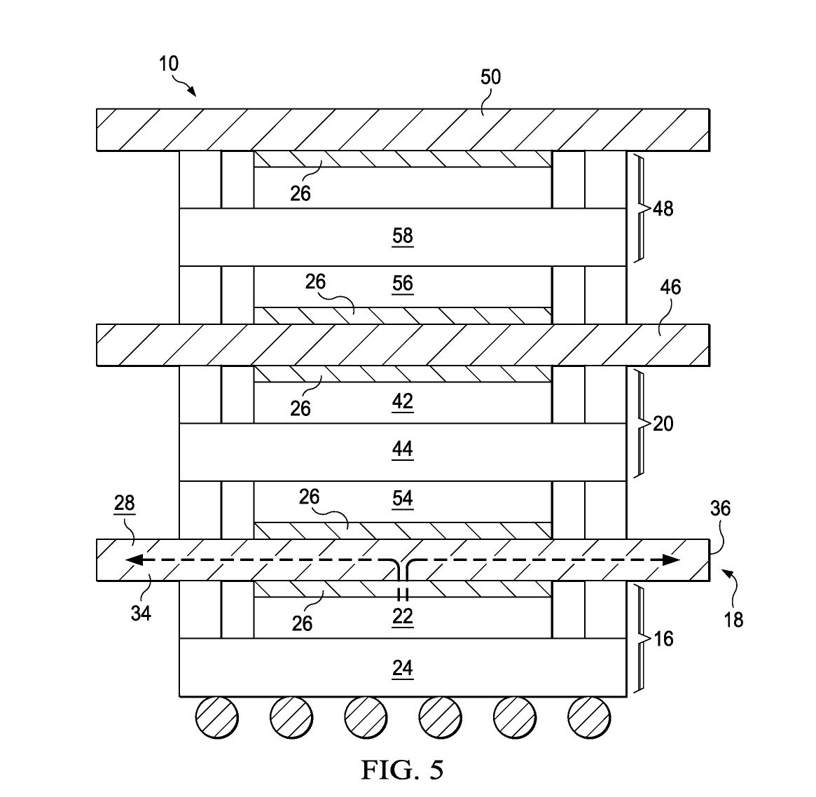

Referring now to FIG. 5, in an embodiment the first and second heat spreaders 18, 46 of the PoP device 10 are in thermal contact with a first inverted chip 54 and a second inverted chip 56, respectively. In other words, the first heat spreader 18 is engaged with, and dissipates heat from, the first chip 22 and the first inverted chips 54, which are on opposing sides of the first heat spreader 18. Likewise, the second heat spreader 46 is engaged with, and dissipates heat from, the second chip 42 and the second inverted chip 56, which are on opposing sides of the second heat spreader 46. As shown, one of the thermally conductive pads 26 may be inserted between the chips and the heat spreader. In other embodiments, heat spreaders in the PoP device 10 may be in thermal contact with a plurality of chips. For illustration purposes, dashed arrows depicting lateral heat dissipation through one of the heat spreaders 18 have been provided in FIG. 5.

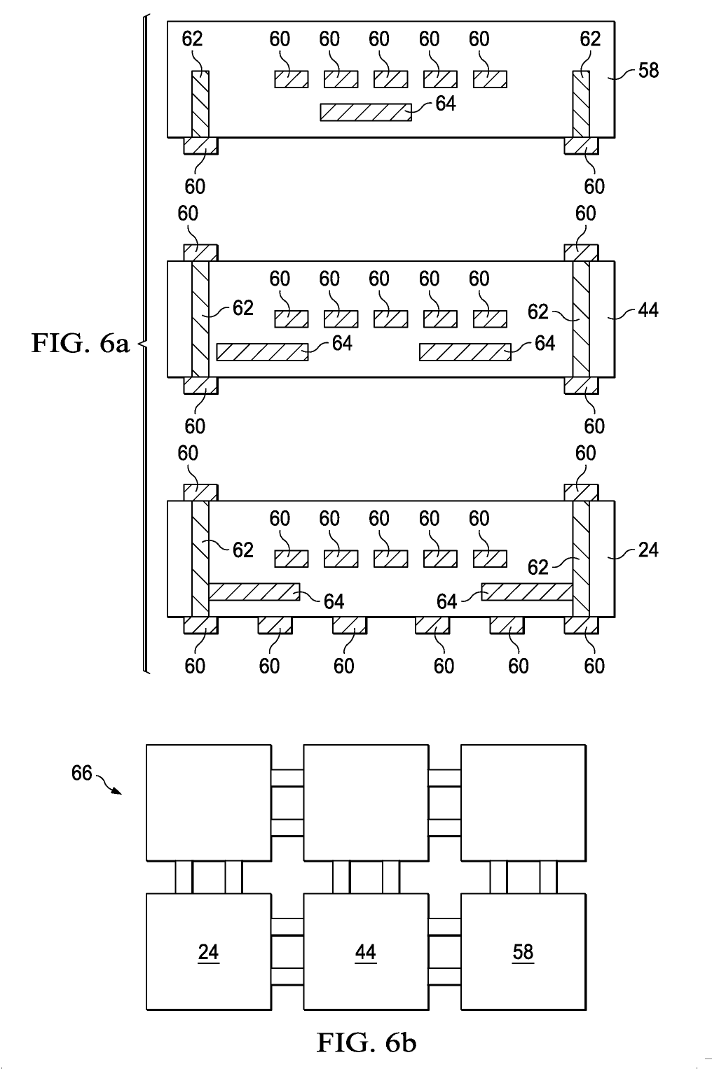

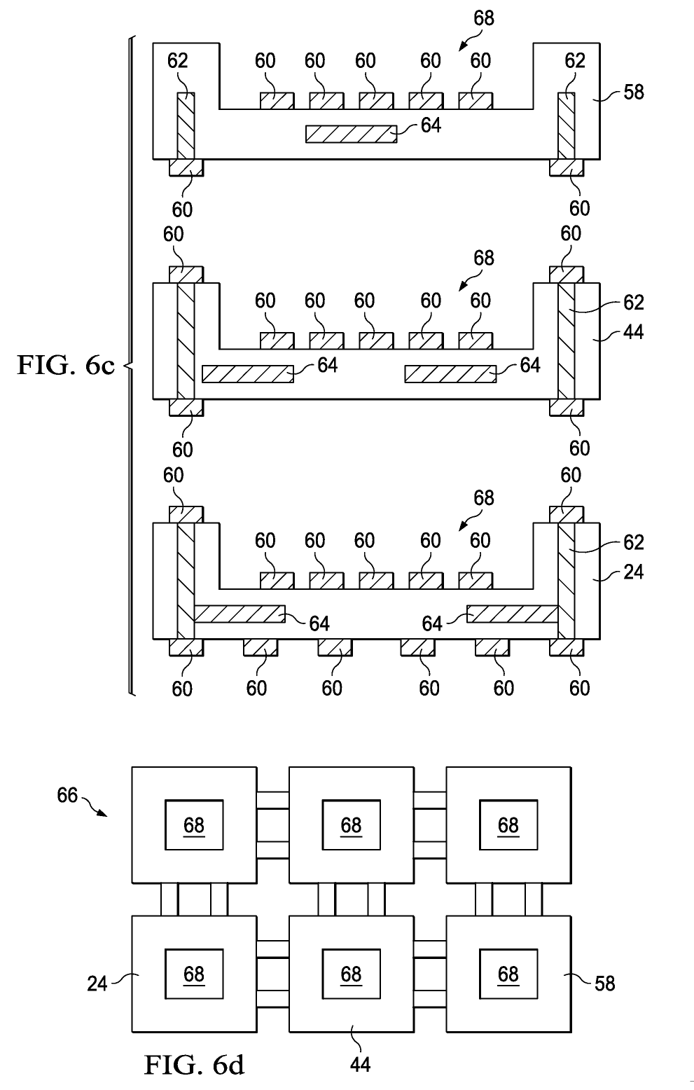

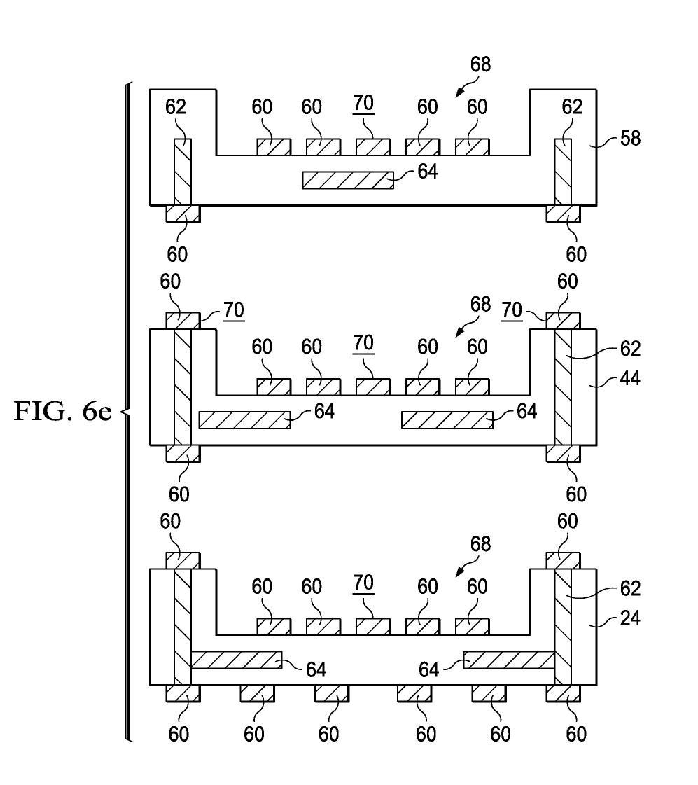

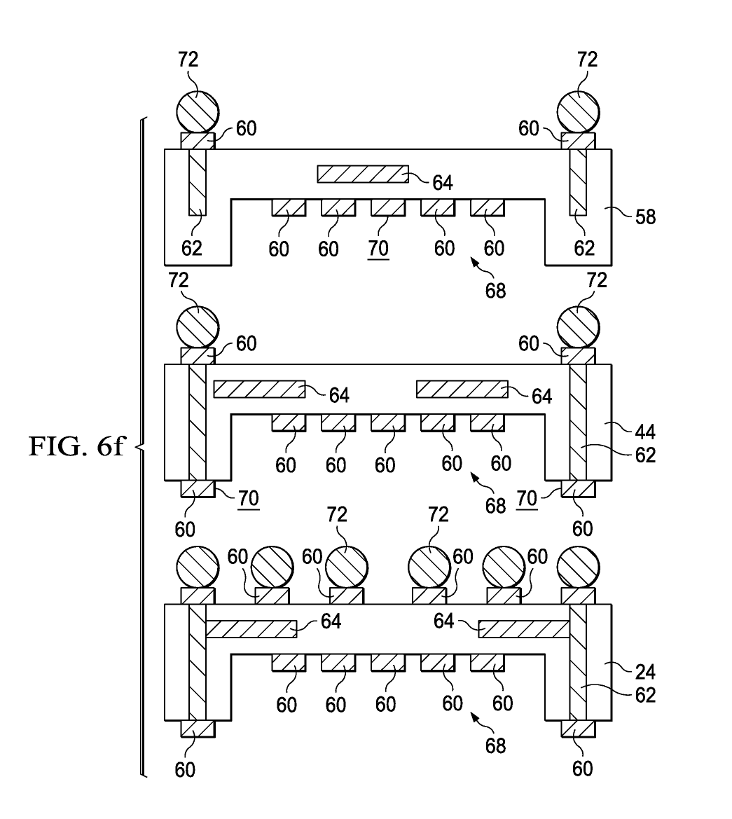

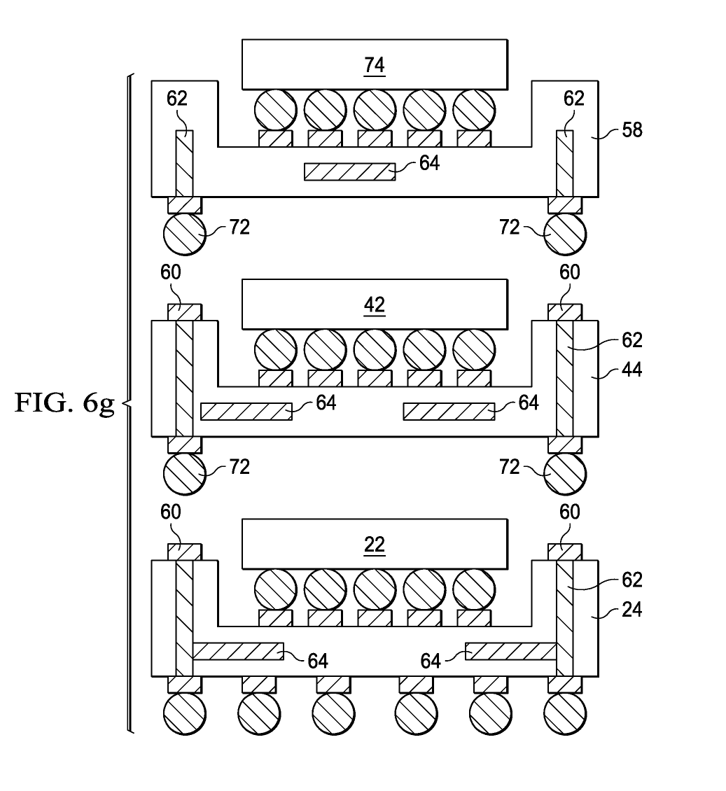

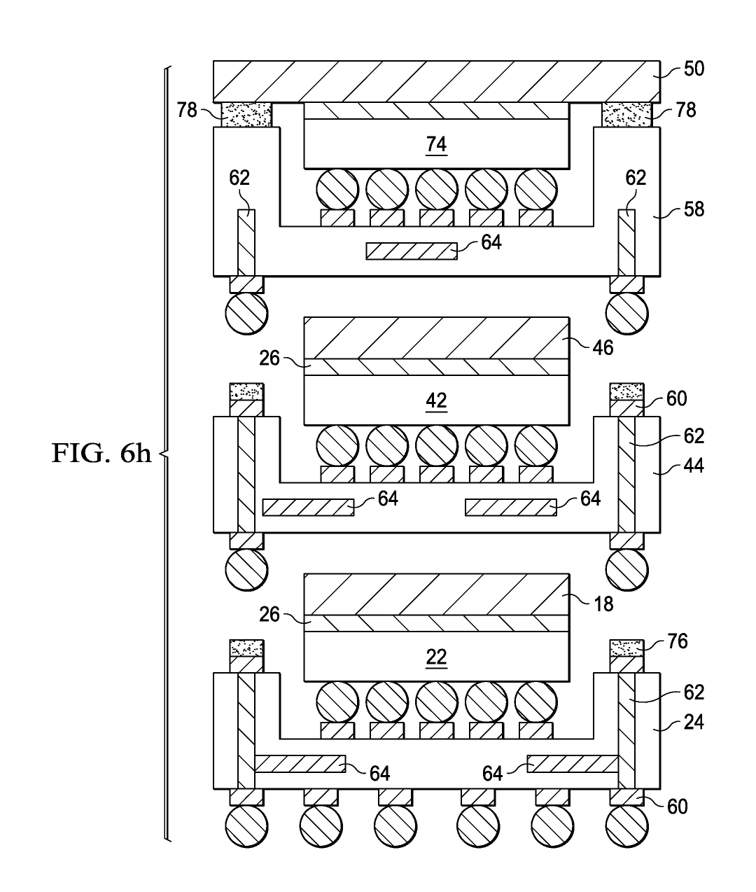

FIGS. 6a-6i collectively illustrate an embodiment of a process of forming an embodiment PoP device 10 incorporating heat spreaders (e.g., first, second, and third heat spreaders 18, 46, 50). In FIG. 6a, the first, second, and third PCB substrates 24, 44, 58, which represent a bottom layer, a second layer, and a third or top layer of the PoP device 10, are fabricated using typical or traditional PCB fabrication processes. During such fabrication process, the first, second, and third PCB substrates 24, 44, 58 may be provided with various contact pads 60, vias 62, and copper traces 64 in a variety of different configurations. As shown in FIG. 6b, a v-cut 66 may be formed between individual substrates (e.g., the first, second, and third PCB substrates 24, 44, 58) to facilitate later separation of the individual substrates.

As shown in FIGS. 6c-6d, a cavity 68 is formed in each of the first, second, and third PCB substrates 24, 44, 58 to exposed the contact pads 60. In an embodiment, the cavity 68 may be formed by etching. In other embodiments, the cavity 68 may be formed by stacking side portions on a flat substrate layer. After the cavity 68 is formed, in FIG. 6e the exposed contact pads 60 are plated with a plating material 70 such as, for example, electroless nickel immersion silver (ENIS), electroless nickel immersion gold (ENIG), electroless nickel electroless palladium (ENEP), electroless nickel electroless palladium immersion gold (ENEPIG), immersion tin (IT), organic solderability preservative (OSP), or other another plating.

Next, the first, second, and third PCB substrates 24, 44, 58 are flipped shown in FIG. 6f. Thereafter, a solder paste is printed on some of the contact pads 60 and solder balls 72 are deposited on contact pads 60. Then, the first, second, and third PCB substrates 24, 44, 58 go through a reflow profile. Next, as shown in FIG. 6g, a stencil process is employed to print solder paste on the contact pads 60 and the first, second, and third chips 22, 42, 74 are inserted in the cavity 68. Thereafter the first, second, and third PCB substrates 24, 44, 58 go through a reflow profile again. With the first, second, and third chips 22, 42, 74 secured in place, the individual chips are separated from each other so that they may be suitably stacked.

In FIG. 6h, solder paste 76 is printed on the contact pads 60 and an adhesive 78 is applied to the uppermost PCB substrate which, in FIG. 6g, is the third PCB substrate 58. Thereafter, the thermally conductive pad 26 or other interface material is disposed on top of each of the first, second, and third chips 22, 42, 74. Next, the first, second, and third heat spreaders 18, 46, 50 are placed in thermal contact with the conductive pads 26 (e.g., thermal interface material) and/or the first, second, and third chips 22, 42, 74. As shown, the third heat spreader 50, which is substantially wider than the first and second heat spreaders 18, 46 in the y-direction in FIG. 6h, also engages the adhesive 78.

With the first, second, and third PCB substrates 24, 44, 58 stacked as generally shown in FIGS. 6h-6i, the first, second, and third packages 16, 20, 48 (which include the first, second, and third PCB substrates 24, 44, 58) go through a reflow profile to secure the substrates together and to form the PoP device 10 shown in FIG. 6i. The PoP device 10 in FIG. 6i may be subjected to various inspections and testing to ensure desired operability and performance.

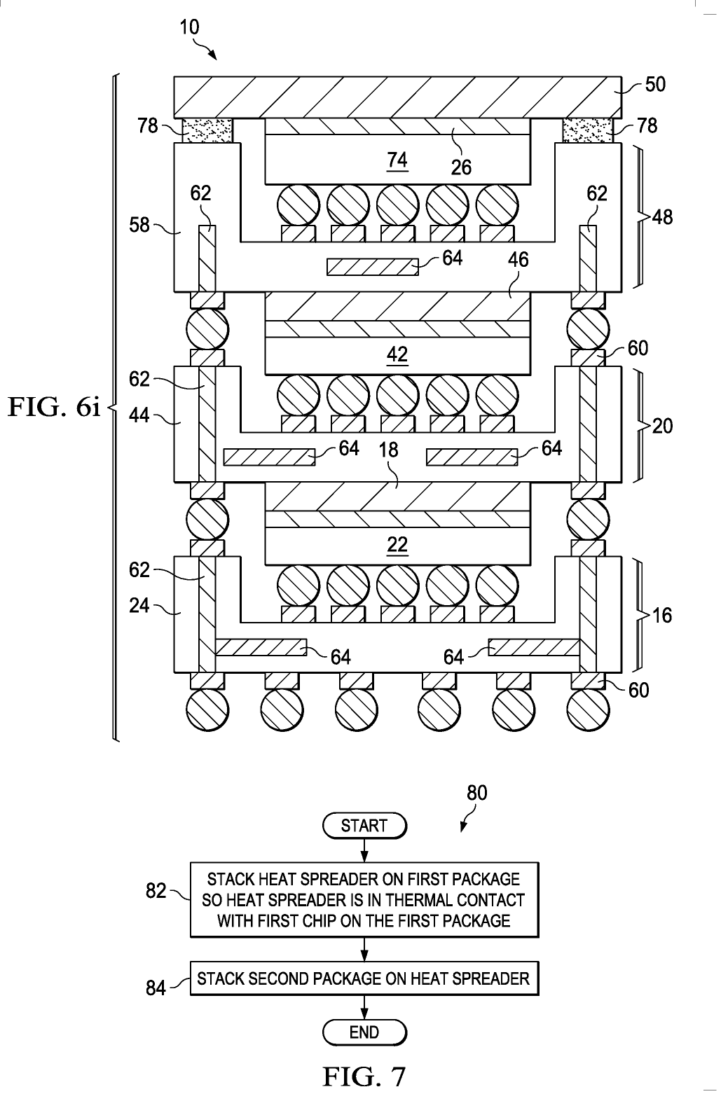

In FIG. 7, an embodiment of a method 80 of forming the PoP device 10 is illustrated in a flow chart. In block 82, the first heat spreader 18 is stacked on the first package 16 so that the first heat spreader 18 is in thermal contact with the first chip 22 mounted on the first package 16. In block 84, the second package 20 is stacked on the first heat spreader 18.

Because of its lighter density, high thermal conductivity, and lower cost, the PoP device 10 incorporating one or more of the heat spreaders is very desirable for mobile devices, laptops and tablets, 200G and 400G routers, power amplifiers, infrastructure equipment, power modules, insulated gate bipolar transistors, and so on. Indeed, the PoP device 10 offers significantly improved thermal management at a substantially reduced cost relative to known package devices.

Embodiments of the invention allow the use of multiple heat spreaders close to each power chip to enhance thermal transfer. Also the way the heat spreaders are arranged, each one of them individually act as a lateral fin to take complete advantage of the convective air flow present in most of the router products. Embodiments of the invention can allow the assembly of smaller sized thermal packages that cannot be constructed with existing heat sink technology. These products can benefit from the advantage of saving space and improving thermal management. For example, substantially better thermal management can be achieved at a significantly reduced cost.

While the disclosure has been made with reference to illustrative embodiments, this description is not intended to be construed in a limiting sense. Various modifications and combinations of the illustrative embodiments, as well as other embodiments, will be apparent to persons skilled in the art upon reference to the description. It is therefore intended that the appended claims encompass any such modifications or embodiments.

What is claimed is:

1. A package-on-package (PoP) device, comprising:
a first package including a first chip mounted on a first substrate;
a heat spreader stacked on the first package, the heat spreader in thermal contact with the first chip; and
a second package stacked on the heat spreader.

2. The device of claim 1, wherein the heat spreader includes carbon fibers.

3. The device of claim 1, wherein the heat spreader is formed from at least one of copper, aluminum, and diamond.

4. The device of claim 1, wherein ends of the heat spreader extend beyond a periphery of the first package.

5. The device of claim 1, wherein ends of the heat spreader extend beyond a periphery of the first package and the second package.

6. The device of claim 1, wherein a thermally conductive pad is disposed between the heat spreader and the first chip of the first package.

7. The device of claim 1, wherein the heat spreader includes metal plated vias.

8. The device of claim 1, wherein the heat spreader is copper plated.

9. The device of claim 1, wherein a heat insulating film is disposed between the heat spreader and a second printed circuit board of the second package.

10. The device of claim 1, wherein the second package includes a second chip, the heat spreader in thermal contact with the second chip.

11. The device of claim 1, wherein the heat spreader has a thermal conductivity of between about six hundred Watts per meter per Kelvin (600 W/(m-K)) and about one thousand five hundred Watts per meter per Kelvin (1500 W/(m-K)).

12. The device of claim 1, wherein the first chip is disposed in a cavity formed in the first substrate.

13. A package-on-package (PoP) device, comprising:
a first package including a first chip mounted on a first substrate;
a first heat spreader stacked on the first package, the first heat spreader in thermal contact with the first chip; and
a second package stacked on the first heat spreader, the second package including a second chip mounted on a second substrate.

14. The device of claim 13, wherein the second chip is in thermal contact with the first heat spreader.

15. The device of claim 13, wherein the second chip is in thermal contact with a second heat spreader stacked on the second package.

16. The device of claim 13, wherein a heat insulating film is disposed between the first heat spreader and the second printed circuit board of the second package.

17. A method of constructing a package-on-package (PoP) device, comprising:
stacking a heat spreader on a first package, the heat spreader in thermal contact with a first chip mounted on the first package; and
stacking a second package on the heat spreader.

18. The method of claim 17, further comprising forming the heat spreader using carbon fibers.

19. The method of claim 17, further comprising orienting the heat spreader such that ends of the heat spreader extend beyond a periphery of the first package and the second package.

20. The method of claim 17, further comprising inserting a thermally conductive pad between the heat spreader and the first chip of the first package.

21. The method of claim 17, further comprising forming metal plated vias through the heat spreader.

22. The method of claim 17, further comprising copper plating the heat spreader.
